(19) United States
(12) Patent Application Publication
(10) Pub. No.: US 2022/0140812 A1
(43) Pub. Date: May 5, 2022

(54) MULTI MIRROR STACK

(71) Applicant: RF360 EUROPE GMBH, Munchen (DE)

(72) Inventors: Ilya LUKASHOV, Munich (DE); Robert Felix BYWALEZ, Munich (DE)

(21) Appl. No.: 17/476,992

(22) Filed: Sep. 16, 2021

Related U.S. Application Data
(60) Provisional application No. 63/108,153, filed on Oct. 30, 2020.

(51) Int. Cl. H03H 9/17; H03H 9/54

(52) U.S. Cl. CPC H03H 9/175; H03H 9/547; H03H 9/545

(57) ABSTRACT

In certain aspects, a chip includes an acoustic resonator, and a mirror under the acoustic resonator. The mirror includes a first plurality of porous silicon layers, and a second plurality of porous silicon layers, wherein the mirror alternates between the first plurality of porous silicon layers and the second plurality of porous silicon layers, and each of the first plurality of porous silicon layers has a higher porosity than each of the second plurality of porous silicon layers.

### CLAIM OF PRIORITY UNDER 35 U.S.C. § 119(e)

The present application for patent claims priority to pending U.S. provisional application No. 63/108,153 titled “MULTI MIRROR STACK” filed Oct. 30, 2020 and assigned to the assignee hereof and hereby expressly incorporated by reference herein as if fully set forth below and for all applicable purposes.

### BACKGROUND

### Field

Aspects of the present disclosure relate generally to multi-layer mirrors, and more particularly, to multi-layer mirrors including alternating layers of low acoustic impedance and high acoustic impedance.

### Background

Acoustic resonators are used in a variety of applications including radio frequency (RF) filters in wireless devices. One type of acoustic resonator is the bulk acoustic wave (BAW) resonator which includes a piezoelectric layer sandwiched between two electrodes. A Bragg mirror may be formed under a BAW resonator to confine acoustic waves to the BAW resonator and achieve a high Q value. A Bragg mirror includes alternating layers of low acoustic impedance and high acoustic impedance material.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes an acoustic resonator and a mirror under the acoustic resonator. The mirror includes a first plurality of porous silicon layers, and a second plurality of porous silicon layers, where the mirror alternates between the first plurality of porous silicon layers and the second plurality of porous silicon layers, and each of the first plurality of porous silicon layers has a higher porosity than each of the second plurality of porous silicon layers.

A second aspect relates to a chip. The chip includes a filter including multiple acoustic resonators. The chip also includes multiple mirrors, where each of the multiple mirrors is under a respective one of the multiple acoustic resonators. Each of the mirrors includes a first plurality of porous silicon layers and a second plurality of porous silicon layers, where the mirror alternates between the first plurality of porous silicon layers and the second plurality of porous silicon layers, and each of the first plurality of porous silicon layers has a higher porosity than each of the second plurality of porous silicon layers.

A third aspect relates to a system. The system includes an antenna, an acoustic resonator coupled to the antenna, and a mirror under the acoustic resonator. The mirror includes a first plurality of porous silicon layers and a second plurality of porous silicon layers, wherein the mirror alternates between the first plurality of porous silicon layers and the second plurality of porous silicon layers, and each of the first plurality of porous silicon layers has a higher porosity than each of the second plurality of porous silicon layers.

These and other aspects will become more fully understood upon a review of the detailed description, which follows. Other aspects, features, and examples will become apparent to those of ordinary skill in the art upon reviewing the following description of specific exemplary aspects in conjunction with the accompanying figures. While features may be discussed relative to certain examples and figures below, all examples can include one or more of the advantageous features discussed herein. In other words, while one or more examples may be discussed as having certain advantageous features, one or more of such features may also be used in accordance with the various examples discussed herein. Similarly, while examples may be discussed below as device, system, or method examples, it should be understood that such examples can be implemented in various devices, systems, and methods.

### BRIEF DESCRIPTION OF THE DRAWINGS

FIG. 1A shows a cross-sectional view of an exemplary bulk acoustic wave (BAW) resonator and a Bragg mirror according to certain aspects of the present disclosure.

FIG. 1B shows a top view of the exemplary BAW resonator according to certain aspects of the present disclosure.

FIG. 2A illustrates an example of electrochemical etching of a silicon substrate to form porous silicon layers of a Bragg mirror according to certain aspects of the present disclosure.

FIG. 2B illustrates formation of a dielectric layer over the Bragg mirror according to certain aspects of the present disclosure.

FIG. 2C illustrates formation of a bottom electrode of a BAW resonator over the dielectric layer and the Bragg mirror according to certain aspects of the present disclosure.

FIG. 2D illustrates an example of bottom electrode planarization according to certain aspects of the present disclosure.

FIG. 2E illustrates an example of deposition of a piezoelectric layer over the bottom electrode according to certain aspects of the present disclosure.

FIG. 2F illustrates formation of a top electrode of the BAW resonator over the piezoelectric layer according to certain aspects of the present disclosure.

FIG. 3A illustrates an example where a first region of a substrate is n-type doped and a second region of the substrate is p-type doped according to certain aspects of the present disclosure.

FIG. 3B illustrates an example of electrochemical etching of the substrate to form porous silicon layers of a first Bragg mirror in the n-type doped region and form porous silicon layers of a second Bragg mirror in the p-type doped region according to certain aspects of the present disclosure.

FIG. 3C illustrates formation of a dielectric layer over the first and second Bragg mirrors according to certain aspects of the present disclosure.

FIG. 3D illustrates formation of a first bottom electrode and a second bottom electrode according to certain aspects of the present disclosure.

FIG. 3E illustrates an example of bottom electrode planarization according to certain aspects of the present disclosure.

FIG. 3F illustrates an example of deposition of a piezoelectric layer over the first bottom electrode and the second bottom electrode according to certain aspects of the present disclosure.

FIG. 3G illustrates formation of a first top electrode and a second top electrode over the piezoelectric layer according to certain aspects of the present disclosure.

FIG. 3H illustrates formation of a first via on the first bottom electrode and a second via on the second bottom electrode according to certain aspects of the present disclosure.

FIG. 4 shows a schematic example of a solidly mounted resonator BAW (SMR-BAW) bandpass filter including BAW resonators coupled in a ladder configuration according to certain aspects of the present disclosure.

FIG. 5 shows an example of a receive path of a wireless device according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

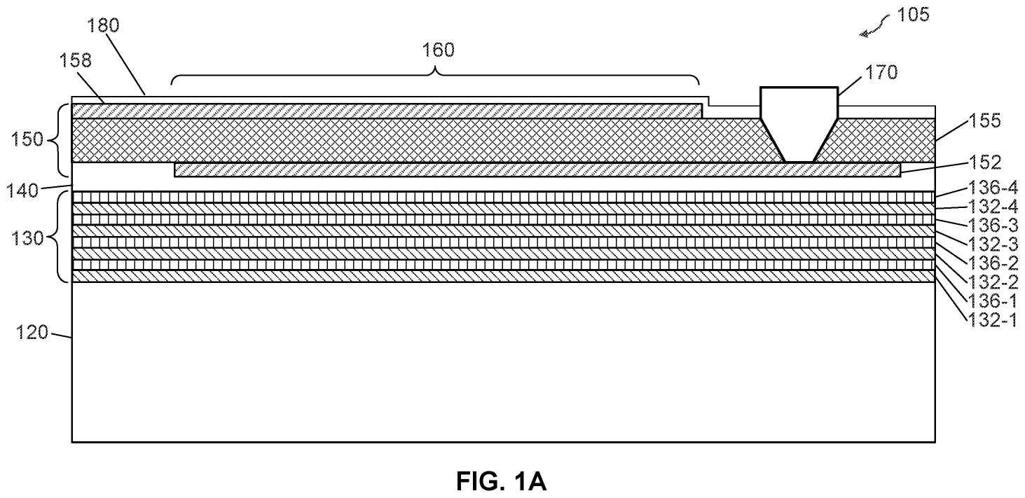

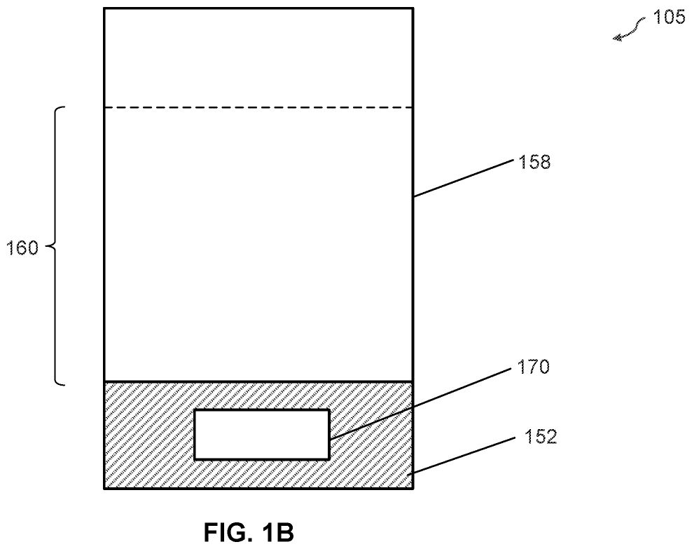

FIG. 1A shows an example of a bulk acoustic wave (BAW) resonator 150 integrated on a chip 105 according to certain aspects. The chip 105 may be part of a wafer before wafer dicing. The BAW resonator 150 includes a bottom electrode 152, a top electrode 158, and a piezoelectric layer 155 disposed between the top electrode 158 and the bottom electrode 152. The electrodes 152 and 158 may comprise tungsten, molybdenum, aluminum, aluminum copper, ruthenium, and/or another material. The piezoelectric layer 155 may comprise aluminum nitride (AlN), zinc oxide (ZnO), or another piezoelectric material. The chip 105 also includes a passivation layer 180 (e.g., silicon nitride) over the BAW resonator 150 to protect the BAW resonator 150 from the external environment. Although FIG. 1A shows one BAW resonator 150, it is to be appreciated that multiple BAW resonators 150 may be integrated on the chip 105.

FIG. 1B shows a top view of the BAW resonator 150. For ease of illustration, the piezoelectric layer 155 and the passivation layer 180 are not shown in FIG. 1B. Although the BAW resonator 150 is shown having a rectangular shape in the example in FIG. 1B, it is to be appreciated that the BAW resonator 150 may have another shape.

The BAW resonator 150 is configured to convert electrical energy from an electrical signal applied to the BAW resonator 150 into acoustic energy in the piezoelectric layer 155 with a resonance frequency that depends on the thicknesses of the piezoelectric layer 155 and the electrodes 152 and 158.

The BAW resonator 150 has an active region 160 corresponding to the overlapping area of the top electrode 158, the piezoelectric layer 155, and the bottom electrode 152. It is desirable to confine acoustic energy to the piezoelectric layer 155 in the active region 160 to reduce energy loss. Acoustic energy leakage in the downward direction may be prevented by forming a Bragg mirror under the BAW resonator 150, as discussed further below.

The top electrode 158 of the BAW resonator 150 may be electrically coupled to another BAW resonator and/or another circuit via a metal interconnect (not shown) coupled to the top electrode 158. In the example shown in FIGS. 1A and 1B, the chip 105 includes a via 170 formed on a portion of the bottom electrode 152 located outside of the active region 160 of the BAW resonator 150. The via 170 passes through an opening in the piezoelectric layer 155. The via 170 is configured to provide electrical access to the bottom electrode 152. In one example, the bottom electrode 152 of the BAW resonator 150 may be electrically coupled to another BAW resonator and/or another circuit via a metal interconnect (not shown) coupled to the top of the via 170.

In the example shown in FIG. 1A, the chip 105 includes a Bragg mirror 130 (also referred to as a Bragg reflector) under the bottom electrode 152 of the BAW resonator 150 to acoustically isolate the BAW resonator 150 from the substrate 120 (e.g., silicon substrate). A dielectric layer 140 may be provided between the bottom electrode 152 and the Bragg mirror 130. The Bragg mirror 130 includes a stack of layers that alternate between high acoustic impedance layers 132-1 to 132-4 and low acoustic impedance layers 136-1 to 136-4. As used herein, a high acoustic impedance corresponds to a first impedance value that is greater than a second impedance value. Each of the layers 132-1 to 132-4 and 136-1 to 136-4 may have a thickness approximately equal to one-quarter of a wavelength of the response frequency of the Bragg mirror 130. It is to be appreciated that the number of layers 132-1 to 132-4 and 136-1 to 136-4 shown in FIG. 1A is exemplary, and that the Bragg mirror 130 may comprise a different number of layers.

The Bragg mirror 130 is configured to reflect acoustic waves from the BAW resonator 150 to prevent the acoustic waves from propagating downward to the substrate 120. Air above the BAW resonator 150 provides a high acoustic reflective interface that prevents acoustic waves from propagating upward. Thus, the Bragg mirror below and the air interface above help confine acoustic energy to the BAW resonator 150. In this example, the filter comprised of the BAW resonator 150 and the Bragg mirror 130 may be referred to as a solidly mounted resonator BAW (SMR-BAW) filter (e.g., as opposed to a film bulk acoustic resonator (FBAR) filter).

In a current approach, tungsten is used for the high acoustic impedance layers 132-1 to 132-4 and silicon oxide (SiO2) is used for the low acoustic impedance layers 136-1 to 136-4. In this approach, the layers of the Bragg mirror 130 are deposited and etched over many process steps to form the Bragg mirror 130, which increases manufacturing complexity and costs. Accordingly, Bragg mirrors that can be fabricated with less complexity and lower costs are desirable.

Aspects of the present disclosure provide a Bragg mirror including layers of porous silicon instead of alternating layers of tungsten and silicon oxide. The porous silicon layers can be formed using an electrochemical etching process, which avoids the multiple process steps used to deposit and etch layers in the current approach, thereby reducing manufacturing complexity and costs. Porosity may be defined as the fraction of void (e.g., hollow space) within a porous silicon layer. Porosity may be given as a percentage. Porosity may be determined by weight measurement, for example. A stack of porous silicon layers (e.g., a multi-stack) may be fabricated on a substrate. In certain aspects, the porosity of the porous silicon layers can be adjusted during electrochemical etching to create alternating layers of low acoustic impedance porous silicon and high acoustic impedance porous silicon. In certain aspects, the acoustic impedances and properties of Bragg mirrors on a chip may be tailored individually by doping the silicon region for each layer of the Bragg mirror individually, as discussed further below. In addition, the porous silicon layers provide favorable thermal isolation of the active area of a BAW resonator against a silicon substrate. This enhances the thermal flow towards the interconnects and reduces the heat absorption by the substrate, enabling devices (e.g., BAW resonator) to operate at higher power levels.

In certain aspects, the high acoustic impedance layers 132-1 to 132-4 and the low acoustic impedance layers 136-1 to 136-4 comprise porous silicon layers in which the porosity of the porous silicon in the low acoustic impedance layers 136-1 to 136-4 is higher than (greater than) the porosity of the porous silicon in the high acoustic impedance layers 132-1 to 132-4. In this example, the higher porosity of the porous silicon in the low acoustic impedance layers 136-1 to 136-4 lowers the acoustic impedance of the low acoustic impedance layers 136-1 to 136-4 compared with the high acoustic impedance layers 132-1 to 132-4. In one example, the porosity of the various porous silicon layers may range between about 20% and 70%, where the porosity of the porous silicon in the high acoustic impedance layers 132-1 to 132-4 is lower than the porosity of the porous silicon in the low acoustic impedance layers 136-1 to 136-4. According to one aspect, for example, the porosity of the porous silicon in the low acoustic impedance layers 136-1 to 136-4 may range be between about 20% and 70% or, more specifically, between about 50% and 70%, while the porosity of the porous silicon in the high acoustic impedance layers 132-1 to 132-4 for the given aspect may range between about 20% and 40%. It is to be appreciated that the preceding ranges are exemplary and non-limiting. It is also to be appreciated that the positions of the high acoustic impedance layers 132-1 to 132-4 and the low acoustic impedance layers 136-1 to 136-4 may be interchanged with respect to the example shown in FIG. 1A.

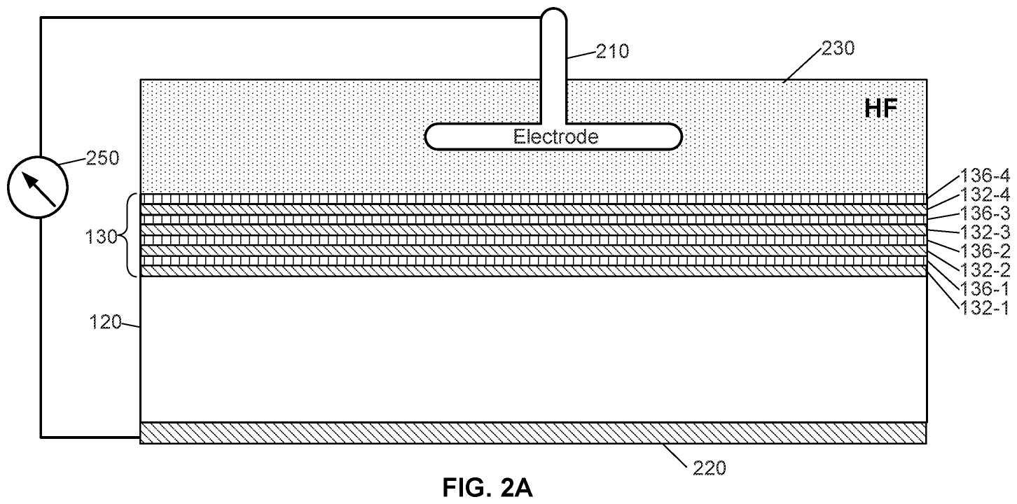

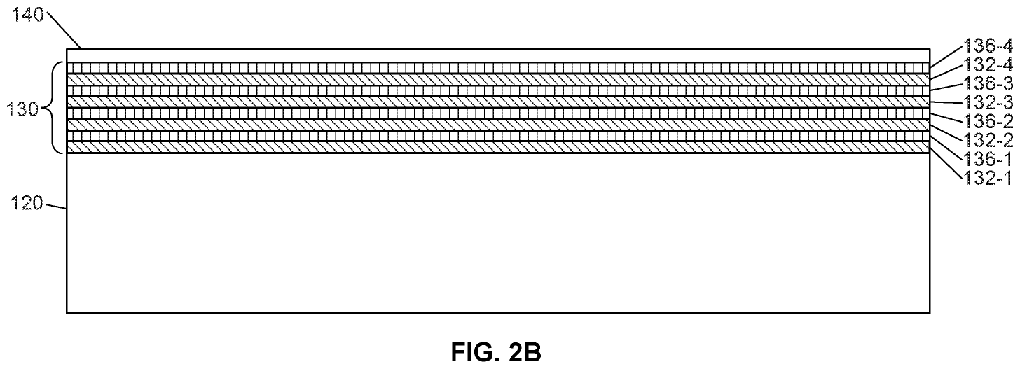

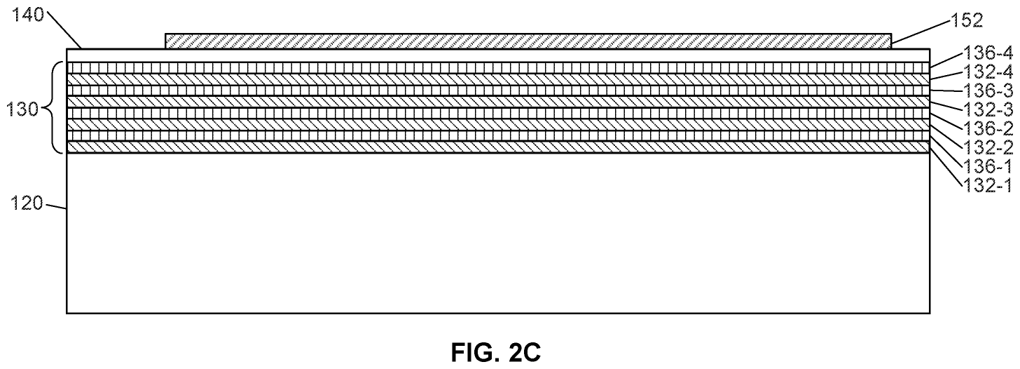

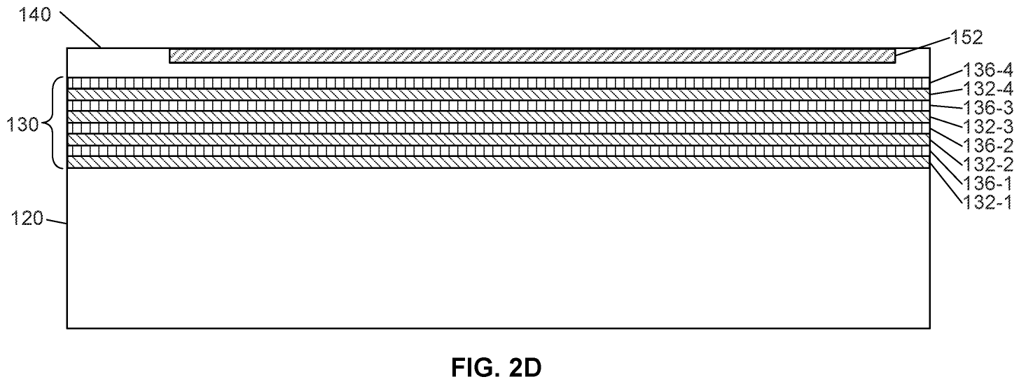

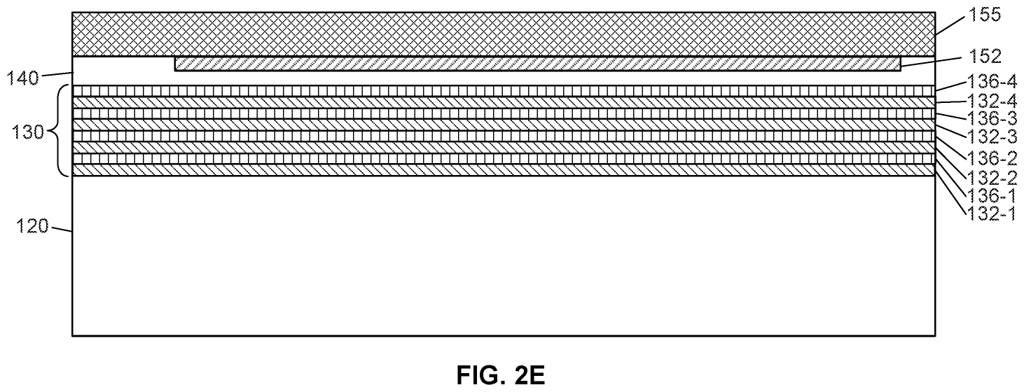

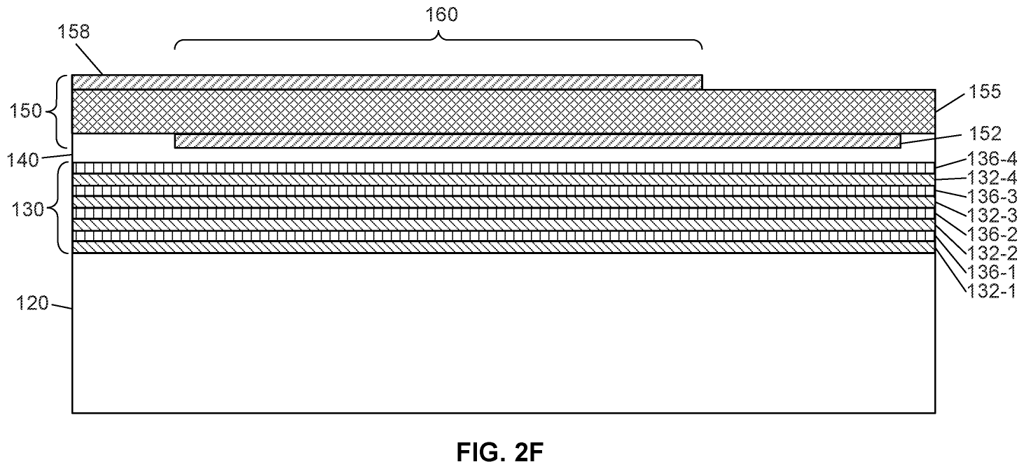

FIGS. 2A to 2F illustrate a formation of an exemplary SMR-BAW filter on a chip, according to some aspects of the disclosure. As illustrated, and as explained in greater detail below, the chip (e.g., similar to the chip 105 as shown and described in FIGS. 1A and 1B) may be formed on a substrate and may include an acoustic resonator (e.g., similar to the BAW resonator 150 as shown and described in FIGS. 1A and 1B) and a mirror (e.g., similar to the Bragg mirror 130 as shown and described in FIG. 1A) under the acoustic resonator. The mirror may include a first plurality of porous silicon layers and a second plurality of porous silicon layers, where the mirror alternates the layers of the pluralities of porous layers between the first plurality of porous silicon layers and the second plurality of porous silicon layers, and each of the first plurality of porous silicon layers has a higher porosity than each of the second plurality of porous silicon layers. It will further be appreciated that an nth porous silicon layer, for example a highest layer (e.g., an uppermost layer) of a multi-layer stack of porous silicon layers, such as layer 136-4 of FIG. 1A, may have a dielectric layer (e.g., similar to the dielectric layer 140 as shown and described in FIG. 1A) above it. In some examples, each of the first plurality of porous silicon layers may have a porosity between 20% and 70%, and the porosity of the second plurality of porous silicon layers may be less than the porosity of the first plurality of porous silicon layers. According to some aspects, the acoustic resonator may include a bottom electrode (e.g., similar to the bottom electrode 152 as shown and described in FIGS. 1A and 1B), a top electrode (e.g., similar to the top electrode 158 as shown and described in FIGS. 1A and 1B), and a piezoelectric layer (e.g., similar to the piezoelectric layer 155 as shown and described in FIGS. 1A and 1B) between the top electrode and the bottom electrode. The mirror may be under the bottom electrode. The dielectric layer may be included between the bottom electrode and the mirror.

An exemplary electrochemical etching process for forming the Bragg mirror 130 is illustrated in FIG. 2A. In this example, the substrate 120 (e.g., silicon substrate) is submerged in a Hydrofluoric (HF) solution 230 or another type of solution suitable for electrochemical etching. A first electrode 210 at least partially submerged in the HF solution 230 may be provided above the silicon substrate 120. A second electrode 220 may be coupled to the backside of the substrate 120 as shown in the example of FIG. 2A. The first electrode 210 may comprise platinum or another material, and the second electrode 220 may comprise titanium, tungsten, or another material. A variable current source 250 is electrically coupled between the first electrode 210 and the second electrode 220. The region of the substrate 120 in which the Bragg mirror 130 is to be formed may be p-type doped, n-type doped, or undoped. For the example of p-type doped or n-type doped, the region of the substrate 120 in which the Bragg mirror 130 is to be formed may be doped using ion implantation or local diffusion before the electrochemical etching process.

During the electrochemical etching process, the variable current source 250 passes a current between the first electrode 210 and the second electrode 220, which causes the silicon substrate 120 to electrochemically react with the HF solution 230, forming voids in the silicon substrate 120 and thus forming porous silicon. The porosity of the layers 132-1 to 132-4 and 136-1 to 136-4 is controlled by controlling the current level of the variable current source 250. Generally, a higher current increases porosity and a lower current decreases porosity. Thus, in this example, the variable current source 250 may alternate between a first current level to form the low acoustic impedance layers 136-1 to 136-4 and a second current level to form the high acoustic impedance layers 132-1 to 132-4 in which the first current level is higher than (greater than) the second current level to give the low acoustic impedance layers 136-1 to 136-4 higher porosity. In this example, the thickness of each layer may be controlled by controlling the time duration of the current used to form the layer. Note that FIG. 2A depicts the silicon substrate 120 at the end of the electrochemical etching process, after the formation of the interleaved layers 132-1 to 132-4 and 136-1 to 136-4 of the Bragg mirror 130 in the silicon substrate 120.

FIG. 2B shows deposition of a dielectric layer 140 over the Bragg mirror 130 to seal the Bragg mirror 130 according to certain aspects.

FIG. 2C shows formation of the bottom electrode 152 over the dielectric layer 140 and the Bragg mirror 130 according to certain aspects. The bottom electrode 152 may be formed by depositing a metal layer on the dielectric layer 140 and etching the metal layer to form the bottom electrode 152 (e.g., using photolithography).

FIG. 2D illustrates an example of bottom electrode planarization according to certain aspects. In this example, additional dielectric material may be deposited on the wafer and the bottom electrode 152 may be planarized (e.g., using chemical mechanical polishing or another type of planarization). The planarization step is optional and may be omitted in some implementations.

FIG. 2E shows deposition of the piezoelectric layer 155 over the bottom electrode 152 according to certain aspects. The piezoelectric layer 155 may comprise aluminum nitride (AlN), zinc oxide (ZnO), or another piezoelectric material.

FIG. 2F shows formation of the top electrode 158 of the BAW resonator 150 over the piezoelectric layer 155 according to certain aspects. The top electrode 158 may be formed by depositing a metal layer on the piezoelectric layer 155 and etching the metal layer to form the top electrode 158 (e.g., using photolithography). The active region 160 of the BAW resonator 150 corresponds to the overlapping area of the top electrode 158, the piezoelectric layer 155, and the bottom electrode 152, as shown in FIG. 2F.

After formation of the top electrode 158, the via 170 (shown in FIGS. 1A and 1B) may be formed, for example, by etching an opening in the piezoelectric layer 155 and filling the opening with a metal to form the via 170. According to some aspects, the via 170 may protrude from the piezoelectric layer 155 and the passivation layer 180.

In certain aspects, Bragg mirrors integrated on the chip 105 may be doped differently to tailor the acoustic impedances and properties of each Bragg mirror individually. These aspects take advantage of the fact that the acoustic impedance of porous silicon is affected by the doping type and doping concentration of the porous silicon. This allows the acoustic impedances of a Bragg mirror to be tailored individually by adjusting the doping type and/or the doping concentration of the Bragg mirror, as discussed further below.

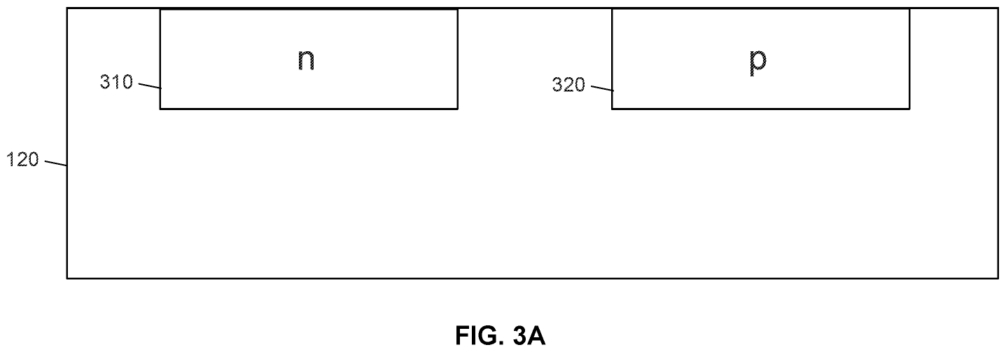

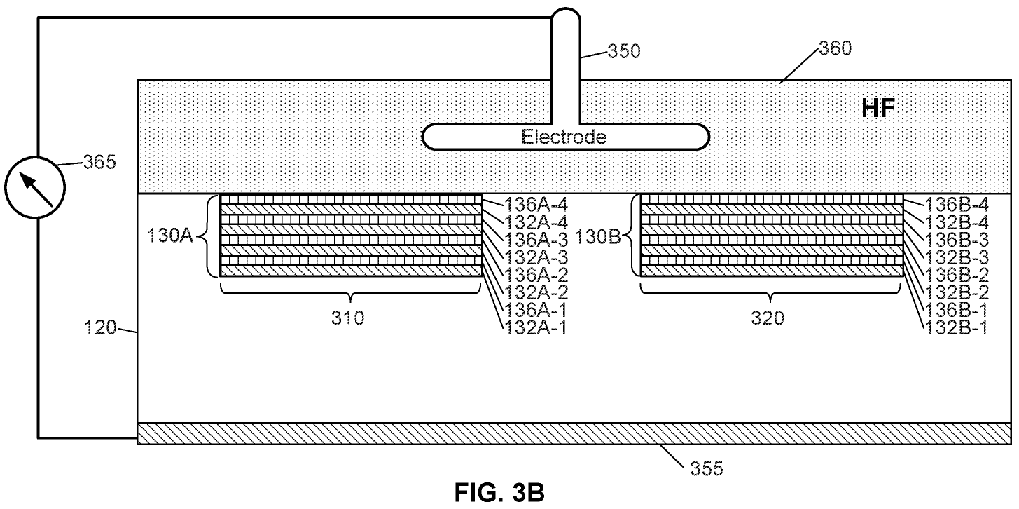

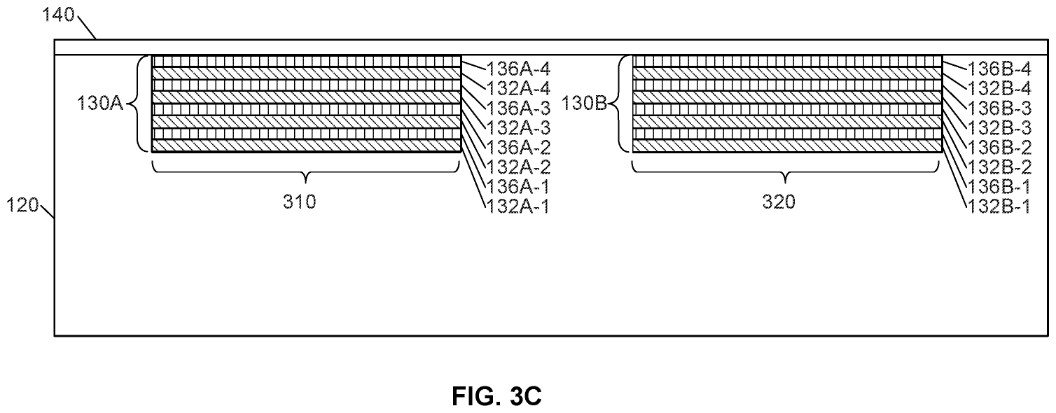

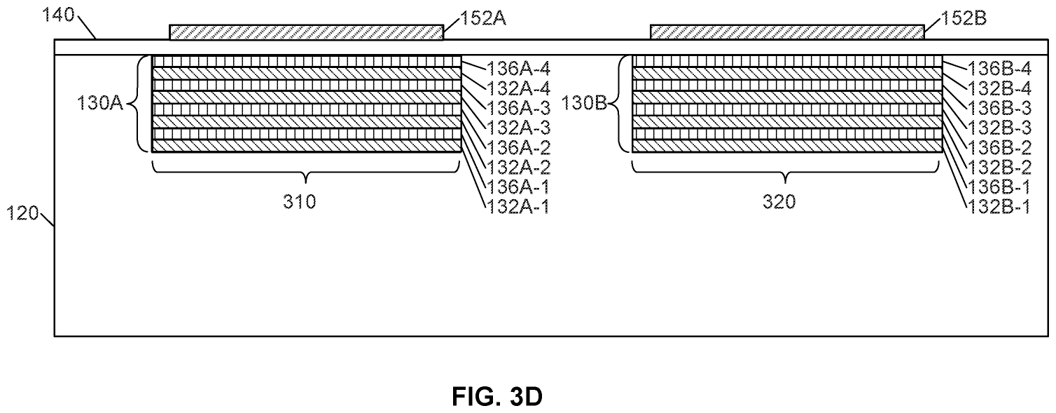

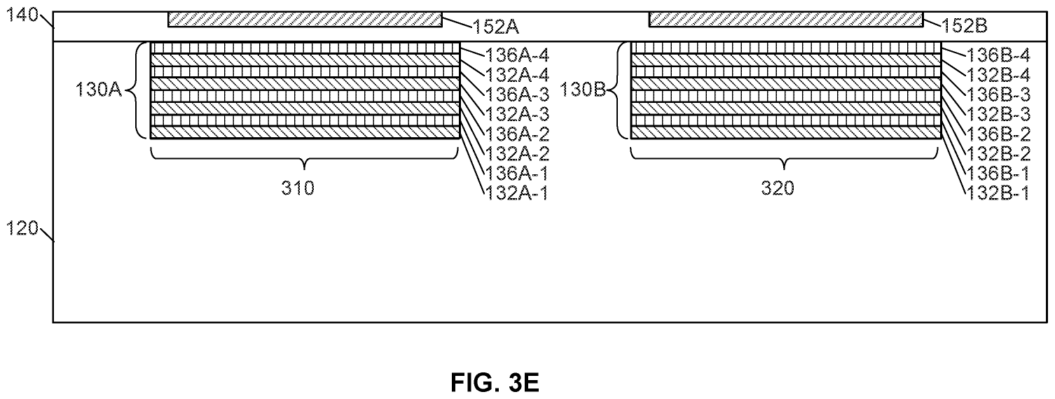

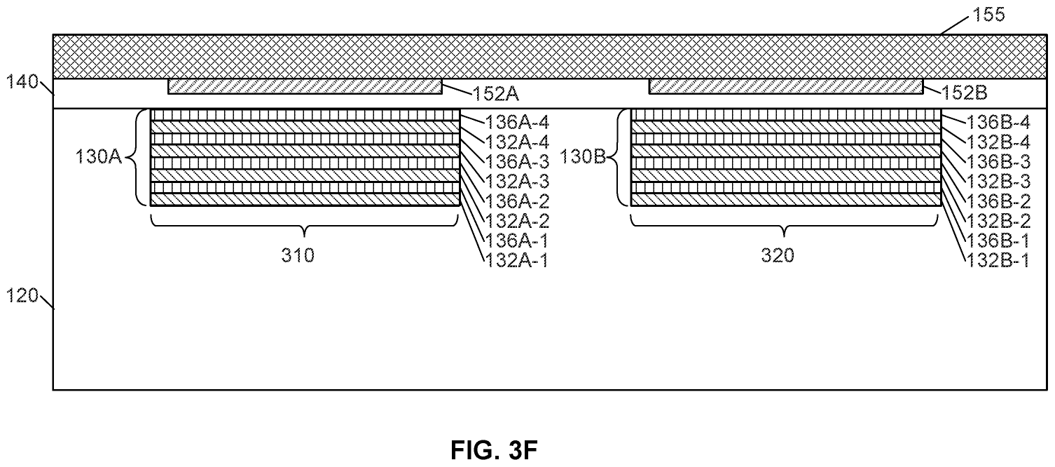

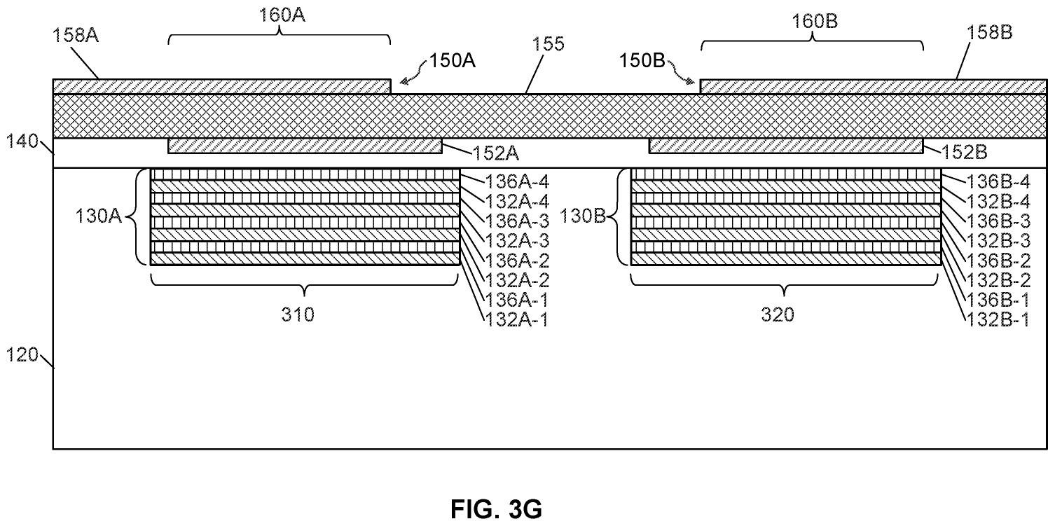

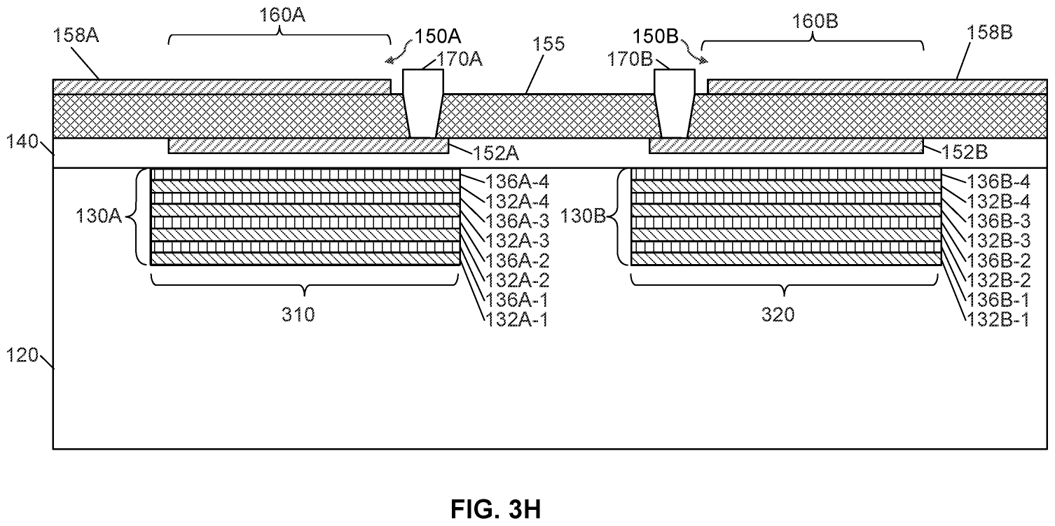

FIG. 3A shows an example in which a first doped region 310 and a second doped region 320 are formed in the substrate 120 (silicon substrate). In this example, the first doped region 310 is n-type doped (i.e., doped with an n-type dopant) and the second doped region 320 is p-type doped (i.e., doped with a p-type dopant). Although the first doped region 310 and the second doped region 320 are shown close to each other in FIG. 3A for ease of illustration, it is to be appreciated that the first doped region 310 and the second doped region 320 may be spaced farther apart. Each of the doped regions 310 and 320 may be formed using ion implantation, local diffusion, and/or another doping technique.

FIG. 3B illustrates an exemplary electrochemical etching process for forming a first Bragg mirror 130A in the first doped region 310 and a second Bragg mirror 130B in the second doped region 320. In this example, the substrate 120 (e.g., silicon substrate) is submerged in a Hydrofluoric (HF) solution 360 with a first electrode 350 at least partially submerged in the HF solution 360 above the silicon substrate 120 and a second electrode 355 placed in contact with the backside of the substrate 120 (e.g., silicon substrate). A variable current source 365 is electrically coupled between the first electrode 350 and the second electrode 355.

During the electrochemical etching process, the variable current source 365 passes a current between the first electrode 350 and the second electrode 355, which causes the silicon substrate 120 to electrochemically react with the HF solution 360, forming voids in the silicon substrate 120 and thus forming porous silicon. The porosity of the layers 132A-1 to 132A-4 and 136A-1 to 136A-4 in the first Bragg mirror 130A and the porosity of the layers 132B-1 to 132B-4 and 136B-1 to 136B-4 in the second Bragg mirror 130B are controlled by controlling the current level of the variable current source 365. In this example, the variable current source 365 may alternate between a first current level to form the low acoustic impedance layers 136A-1 to 136A-4 and 136B-1 to 136B-4 and a second current level to form the high acoustic impedance layers 132A-1 to 132A-4 and 132B-1 to 132B-4. The first current level is higher than (greater than) the second current level to give the low acoustic impedance layers 136A-1 to 136A-4 and 136B-1 to 136B-4 higher porosity. In this example, the thickness of each layer may be controlled by controlling the time duration of the current used to form the layer.

In this example, the same electrochemical etching process may be used to form the high acoustic impedance layers 132A-1 to 132A-4 and the low acoustic impedance layers 136A-1 to 136A-4 in the first Bragg mirror 130A, and the high acoustic impedance layers 132B-1 to 132B-4 and the low acoustic impedance layers 136B-1 to 136B-4 in the second Bragg mirror 130B. Because the regions of the first and second Bragg mirrors 130A and 130B are doped independently, the respective acoustic impedances of the first and second Bragg mirrors 130A and 130B may be individually tailored by individually setting the doping type and/or the doping concentration for the region of each Bragg mirror, as discussed further below.

It is to be appreciated that the electrochemical etching process may generate porous silicon layers in areas of the substrate 120 located outside of the doped regions 310 and 320. These porous silicon layers are not shown in FIG. 3B for ease of illustration.

FIG. 3C shows deposition of a dielectric layer 140 over the first and second Bragg mirrors 130A and 130B. The dielectric layer 140 may seal the first and second Bragg mirrors 130A and 130B according to certain aspects.

FIG. 3D shows formation of a first bottom electrode 152A over the dielectric layer 140 and the first Bragg mirror 130A, and formation of a second bottom electrode 152B over the dielectric layer 140 and the second Bragg mirror 130B according to certain aspects. The first and second bottom electrodes 152A and 152B may be formed by depositing a metal layer on the dielectric layer 140, etching a first portion of the metal layer to form the first bottom electrode 152A, and etching a second portion of the metal layer to form the second bottom electrode 152B (e.g., using photolithography).

FIG. 3E illustrates an example of bottom electrode planarization according to certain aspects. In this example, additional dielectric material may be deposited on the wafer and the first and second bottom electrodes 152A and 152B may be planarized (e.g., using chemical mechanical polishing or another type of planarization). The planarization step is optional and may be omitted in some implementations.

FIG. 3F shows deposition of the piezoelectric layer 155 over the first and second bottom electrodes 152A and 152B according to certain aspects. The piezoelectric layer 155 may comprise aluminum nitride (AlN), zinc oxide (ZnO), or another piezoelectric material.

FIG. 3G shows formation of a first top electrode 158A and a second top electrode 158B over the piezoelectric layer 155 according to certain aspects. The first and second top electrodes 158A and 158B may be formed by depositing a metal layer on the piezoelectric layer 155, etching a first portion of the metal layer to form the first top electrode 158A, and etching a second portion of the metal layer to form the second top electrode 158B (e.g., using photolithography). The first top electrode 158A overlaps the first bottom electrode 152A to form a first BAW resonator 150A. The second top electrode 158B overlaps the second bottom electrode 152B to form a second BAW resonator 150B. The active region 160A of the first BAW resonator 150A corresponds to the overlapping area of the first top electrode 158A, the piezoelectric layer 155, and the first bottom electrode 152A. The active region 160B of the second BAW resonator 150B corresponds to the overlapping area of the second top electrode 158B, the piezoelectric layer 155, and the second bottom electrode 152B.

In certain aspects, the mass loading of the top electrode 158A of the first BAW resonator 150A may be adjusted (i.e., tuned) to achieve a desired resonance frequency for the first BAW resonator 150A based on the dependency of the resonance frequency on the mass loading of the top electrode 158A. The adjustment in the mass loading may be additive in which additional metal or dielectric is deposited on the top electrode 158A to achieve the desired resonance frequency for the first BAW resonator 150A, or subtractive in which metal is etched away or trimmed from the top electrode 158A to achieve a mass loading corresponding to the desired resonance frequency for the first BAW resonator 150A. Similarly, the mass loading of the top electrode 158B of the second BAW resonator 150B may be adjusted (i.e., tuned) to achieve a desired resonance frequency for the second BAW resonator 150B. Thus, the resonance frequencies of the first BAW resonator 150A and the second BAW resonator 150B may be independently adjusted (i.e., tuned) by independently adjusting (i.e., tuning) the mass loading of their top electrodes 158A and 158B to achieve desired resonance frequencies for the first BAW resonator 150A and the second BAW resonator 150B.

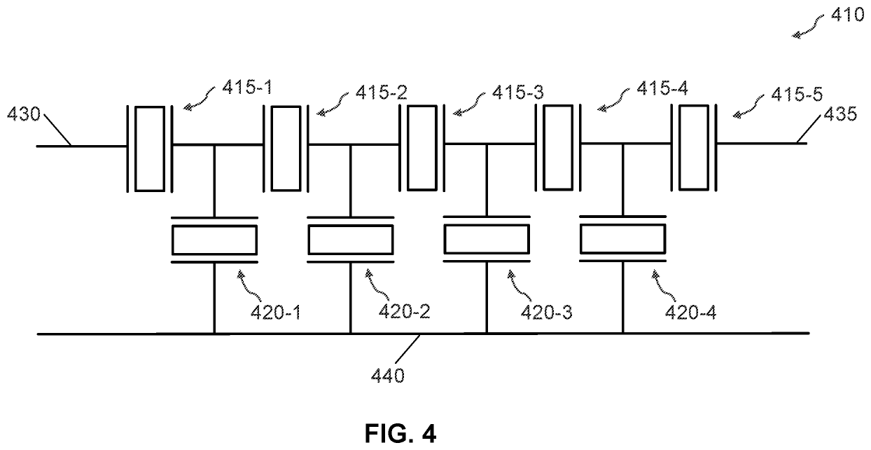

FIG. 3H shows an example in which a first via 170A is formed on the first bottom electrode 152A outside of the active region 160A to provide electrical access to the first bottom electrode 152A. The first via 170A may be formed, for example, by etching an opening in the piezoelectric layer 155 and filling the opening with a metal to form the first via 170A. FIG. 3H also shows an example in which a second via 170B is formed on the second bottom electrode 152B outside of the active region 160B to provide electrical access to the second bottom electrode 152B. The second via 170B may be formed, for example, by etching an opening in the piezoelectric layer 155 and filling the opening with a metal to form the second via 170B. As used herein, each via may be defined by internal walls of the piezoelectric layer 155. A passivation layer (not shown) may be provided on the piezoelectric layer 155, the top electrode 158A, and/or the top electrode 158B; the passivation layer is not shown in FIG. 4 to avoid cluttering the drawing.

The respective acoustic impedance and reflectivity of the first Bragg mirror 130A and the second Bragg mirror 130B may be individually tailored, for example, by independently setting the doping type and/or doping concentration of the first Bragg mirror 130A and the second Bragg mirror 130B. For example, an n-type dopant produces larger diameter pores than a p-type dopant for a given electrochemical etching process. Accordingly, the n-type dopant results in higher porosity (e.g., the porosity associated with the n-type dopant is greater than the porosity associated with the p-type dopant) and, therefore, lower acoustic impedance than the p-type dopant. Thus, in the example in FIG. 3H where the first Bragg mirror 130A is formed in an n-type doped region (e.g., the first doped region 310) and the second Bragg mirror 130B is formed in a p-type doped region (e.g., the second doped region 320), the high acoustic impedance layers 132A-1 to 132A-4 in the first Bragg mirror 130A may have a lower acoustic impedance than the high acoustic impedance layers 132B-1 to 132B-4 in the second Bragg mirror 130B. Similarly, the low acoustic impedance layers 136A-1 to 136A-4 in the first Bragg mirror 130A may have a lower acoustic impedance than the low acoustic impedance layers 136B-1 to 136B-4 in the second Bragg mirror 130B. Thus, the acoustic impedances of the first Bragg mirror 130A and the second Bragg mirror 130B may be individually tailored by forming the first Bragg mirror 130A and the second Bragg mirror 130B in doped regions having different dopant types and/or doping concentrations.

The reflectivity of each respective Bragg mirror 130A and 130B is dependent on the acoustic impedance of the respective Bragg mirror. Since the acoustic impedances of the respective Bragg mirrors are affected by the doping type and/or doping concentration associated with the respective Bragg mirror, the reflectivity of each respective Bragg mirror 130A and 130B may be individually tailored by individually setting the doping type and/or doping concentration. For example, the reflectivity of each respective Bragg mirror 130A and 130B may be tailored to achieve a high reflectivity for frequencies within a passband of its associated BAW resonator 150A and 150B. As used herein, the term “high reflectivity” (when applied to a Bragg mirror) describes a first value of reflectivity of a Bragg mirror realized for frequencies inside the passband of its associated BAW resonator that is greater than a second value of reflectivity of the Bragg mirror realized for frequencies outside the passband of the associated BAW resonator. According to some aspects, the passband may be defined by the −3 dB points of the BAW resonator. The high reflectivity of each respective Bragg mirror 130A and 130B within the BAW resonator passband may enhance the performance of the associated BAW resonator 150A and 150B.

BAW resonators may be used in a variety of applications. For example, BAW resonators may be used to form bandpass filters, notch filters, multiplexers, duplexers, extractors, etc. In this regard, FIG. 4 shows a schematic example of a solidly mounted resonator BAW (SMR-BAW) bandpass filter 410, including BAW resonators coupled in a ladder configuration according to certain aspects of the present disclosure. More particularly, FIG. 4 shows a schematic example of an SMR-BAW bandpass filter 410 including series BAW resonators 415-1 to 415-5 and shunt BAW resonators 420-1 to 420-4 (also referred to as parallel BAW resonators) coupled in a ladder configuration, according to some aspects described herein. Each of the BAW resonators 415-1 to 415-5 and 420-1 to 420-4 may be implemented with the exemplary BAW resonator 150 (e.g., each of the BAW resonators 415-1 to 415-5 and 420-1 to 420-4 is a separate instance of the BAW resonator 150). In this example, the series BAW resonators 415-1 to 415-5 are coupled in series between a first terminal 430 and a second terminal 435 of the SMR-BAW bandpass filter 410. Each shunt BAW resonator 420-1 to 420-4 is coupled between a respective one of the series BAW resonators and a third terminal 440 of the SMR-BAW bandpass filter 410. For example, shunt BAW resonator 420-1 is coupled between series BAW resonator 415-1 and the third terminal 440, shunt BAW resonator 420-2 is coupled between series BAW resonator 415-2 and the third terminal 440, and so forth.

It is to be appreciated that the SMR-BAW bandpass filter 410 may include a different number of series BAW resonators and a different number of shunt BAW resonators than shown in the example in FIG. 4. In other examples, a filter may include BAW resonators coupled in a lattice configuration or a combination of a ladder configuration and a lattice configuration.

In the example of FIG. 4, the respective resonance frequencies of the series BAW resonators 415-1 to 415-5 and the shunt BAW resonators 420-1 to 420-4 may each be tuned so that, when taken together, a desired overall passband response of the SMR-BAW bandpass filter 410 is achieved. Tuning of the respective resonance frequencies may be carried out according to aspects described herein. For example, and as discussed above, the resonance frequencies of the series BAW resonators 415-1 to 415-5 and the shunt BAW resonators 420-1 to 420-4 may be independently adjusted (i.e., tuned) by independently adjusting the mass loading of the top electrodes of the series BAW resonators 415-1 to 415-5 and the mass loading of the top electrodes of the shunt BAW resonators 420-1 to 420-4.

Also, in this example, the reflectivities of the Bragg mirrors for the series BAW resonators 415-1 to 415-5 may be tailored by setting the doping type and/or doping concentration of the Bragg mirrors for the series BAW resonators 415-1 to 415-5, and the reflectivities of the Bragg mirrors for the parallel BAW resonators 420-1 to 420-4 may be tailored by setting the doping type and/or doping concentration of the Bragg mirrors for the parallel BAW resonators 420-1 to 420-4. For example, the respective reflectivities of the Bragg mirrors associated with the series BAW resonators 415-1 to 415-5 may be tailored to provide high reflectivity at frequencies within the passbands of the respective series BAW resonators 415-1 to 415-5. Likewise, the respective reflectivities of the Bragg mirrors associated with the shunt BAW resonators 420-1 to 420-4 may be tailored to provide high reflectivity at frequencies within the passbands of the respective shunt BAW resonators 420-1 to 420-4. At frequencies outside of the respective passbands, the respective Bragg mirrors may exhibit reflectivities that are less than those exhibited within the respective passbands.

For example, the Bragg mirrors for the series BAW resonators 415-1 to 415-5 may be formed in n-type doped regions and the Bragg mirrors for the shunt BAW resonators 420-1 to 420-4 may be formed in p-type doped regions to achieve desired reflection coefficients for the series BAW resonators 415-1 to 415-5 and the shunt BAW resonators 420-1 to 420-4. The reflection coefficient may be defined as a value that quantifies how much of an electromagnetic wave is reflected from an input (e.g., first terminal 430) of a circuit (e.g., the SMR-BAW bandpass filter 410). The reflection coefficient may be given as a ratio of the amplitude of the reflected wave to the incident wave. In general, each of the series BAW resonators 415-1 to 415-5 and the shunt BAW resonators 420-1 to 420-4 may be tuned to minimize the reflection coefficient at the input of the SMR-BAW bandpass filter 410 for frequencies within the passband of the SMR-BAW bandpass filter 410.

In this example, each of the series BAW resonators 415-1 to 415-5 may be implemented with the exemplary first BAW resonator 150A illustrated in FIG. 3H (e.g., each of the series BAW resonators may be a separate instance of a BAW resonator having a structure similar to the first BAW resonator 150A), and each of the shunt BAW resonators 420-1 to 420-4 may be implemented with the exemplary second BAW resonator 150B illustrated in FIG. 3H (e.g., each of the shunt BAW resonators may be a separate instance of a BAW resonator having a structure similar to the second BAW resonator 150B). Also, in this example, the Bragg mirror for each of the series BAW resonators 415-1 to 415-5 may be implemented with the exemplary Bragg mirror 130A illustrated in FIG. 3H (e.g., each of the Bragg mirrors may be a separate instance of a Bragg mirror having a structure similar to the Bragg mirror 130A, which is formed in an n-type doped region, e.g., first doped region 310), and the Bragg mirror for each of the shunt BAW resonators 420-1 to 420-4 may be implemented with the exemplary Bragg mirror 130B illustrated in FIG. 3H (e.g., each of the Bragg mirrors may be a separate instance of a Bragg mirror having a structure similar to the Bragg mirror 130B, which is formed in a p-type doped region, e.g., second doped region 320).

In another example, the Bragg mirror for each of the series BAW resonators 415-1 to 415-5 may be formed in p-type doped regions and the Bragg mirror for each of the shunt BAW resonators 420-1 to 420-4 may be formed in n-type doped regions to achieve desired reflection coefficients for the series BAW resonators 415-1 to 415-5 and the shunt BAW resonators 420-1 to 420-4 (and overall reflection coefficient of the SMR-BAW bandpass filter 410). In this example, each of the series BAW resonators 415-1 to 415-5 may be implemented with the exemplary second BAW resonator 150B illustrated in FIG. 3H (e.g., each of the series BAW resonators may be a separate instance of a BAW resonator having a structure similar to the second BAW resonator 150B), and each of the shunt BAW resonators 420-1 to 420-4 may be implemented with the exemplary first BAW resonator 150A illustrated in FIG. 3H (e.g., each of the shunt BAW resonators may be a separate instance of a BAW resonator having a structure similar to the first BAW resonator 150A). Also, in this example, the Bragg mirror for each of the series BAW resonators 415-1 to 415-5 may be implemented with the exemplary Bragg mirror 130B illustrated in FIG. 3H (e.g., each of the respective Bragg mirrors may be a separate instance of a Bragg mirror having a structure that may be similar to the Bragg mirror 130B, which is formed in a p-type doped region, e.g., second doped region 320), and the Bragg mirror for each of the shunt BAW resonators 420-1 to 420-4 may be implemented with the exemplary Bragg mirror 130A illustrated in FIG. 3H (e.g., each of the Bragg mirrors may be a separate instance of a Bragg mirror having a structure similar to the Bragg mirror 130A, which is formed in an n-type doped region, e.g., first doped region 310). The preceding examples are provided without limitation. For example, the numbers and arrangement of series BAW resonators and/or shunt BAW resonators and associated Bragg mirrors may be different than those exemplified above.

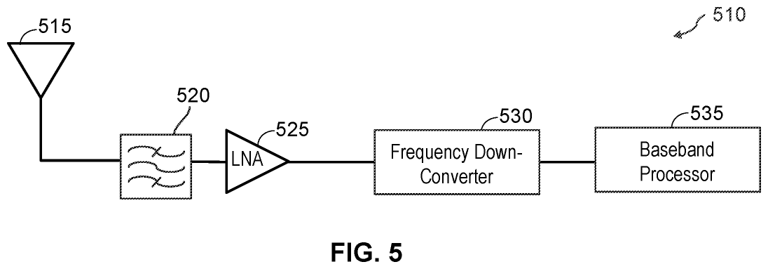

A bandpass filter incorporating BAW resonators may be used in the receive path or the transmit path of a wireless device. In this regard, FIG. 5 shows an example of a receive path 510 of a wireless device according to certain aspects. The receive path 510 includes an antenna 515, a bandpass filter 520, a low noise amplifier (LNA) 525, a frequency down-converter 530, and a baseband processor 535. In this example, the bandpass filter 520 is coupled between the antenna 515 and the input of the LNA 525. The bandpass filter 520 may include BAW resonators (e.g., multiple instances of the BAW resonator 150) coupled to respective Bragg mirrors (e.g., multiple instances of Bragg mirror 130). In other words, the bandpass filter 520 may include one or more bandpass filters configured as SMR-BAW filters according, for example, to some aspects of the present disclosure. In one example, the bandpass filter 520 may be implemented with the exemplary SMR-BAW bandpass filter 410 schematically illustrated in FIG. 4. The frequency down-converter 530 is coupled between the output of the LNA 525 and the baseband processor 535.

In operation, the bandpass filter 520 receives radio frequency (RF) signals from the antenna 515 and filters the received RF signals to pass an RF signal within a desired frequency band (i.e., passband). The LNA 525 amplifies the RF signal from the bandpass filter 520 and the frequency down-converter 530 down converts the amplified RF signal into a baseband signal (e.g., by mixing the RF signal with a local oscillator signal). The baseband processor 535 is configured to process the baseband signal to recover data from the baseband signal. The processing may include sampling, demodulation, decoding, etc.

It is to be appreciated that the receive path 510 is not limited to the exemplary arrangement shown in FIG. 5. For example, it is to be appreciated that, in some implementations, the bandpass filter 520 may be coupled between the LNA 525 and the frequency down-converter 530. It is also to be appreciated that the receive path 510 may include additional elements not shown in FIG. 5.

It is to be appreciated that the present disclosure is not limited to the exemplary terminology used above to describe aspects of the present disclosure. For example, a Bragg mirror may also be referred to as a Bragg reflector or another term.

Implementation examples are described in the following numbered clauses:

1. A chip, comprising:
an acoustic resonator; and
a mirror under the acoustic resonator, the mirror including:
a first plurality of porous silicon layers; and
a second plurality of porous silicon layers, wherein the mirror alternates between the first plurality of porous silicon layers and the second plurality of porous silicon layers, and each of the first plurality of porous silicon layers has a higher porosity than each of the second plurality of porous silicon layers.

2. The chip of clause 1, wherein each of the first plurality of porous silicon layers has a porosity between 20% and 70%.

3. The chip of clause 1 or 2, wherein the mirror is formed in a p-type doped region of a substrate.

4. The chip of clause 1 or 2, wherein the mirror is formed in an n-type doped region of a substrate.

5. The chip of any one of clauses 1 to 4, wherein the acoustic resonator comprises:
a bottom electrode;
a top electrode; and
a piezoelectric layer between the top electrode and the bottom electrode.

6. The chip of clause 5, wherein the mirror is under the bottom electrode.

7. The chip of clause 6, further comprising a dielectric layer between the bottom electrode and the mirror.

8. A chip, comprising:
a filter comprising multiple acoustic resonators; and
multiple mirrors, wherein each of the multiple mirrors is under a respective one of the multiple acoustic resonators, and each of the mirrors includes:
a first plurality of porous silicon layers; and
a second plurality of porous silicon layers, wherein the mirror alternates between the first plurality of porous silicon layers and the second plurality of porous silicon layers, and each of the first plurality of porous silicon layers has a higher porosity than each of the second plurality of porous silicon layers.

9. The chip of clause 8, wherein the multiple acoustic resonators are coupled in a ladder configuration.

10. The chip of clause 8, wherein the multiple acoustic resonators comprise series acoustic resonators and shunt acoustic resonators, the series acoustic resonators are coupled in series between a first terminal and a second terminal of the filter, and each of the shunt acoustic resonators is coupled between a respective one of the series acoustic resonators and a third terminal of the filter.

11. The chip of clause 10, wherein each of the multiple mirrors under a respective one of the series acoustic resonators is formed in an n-type doped region of a substrate, and each of the multiple mirrors under a respective one of the shunt acoustic resonators is formed in a p-type doped region of the substrate.

12. The chip of clause 10, wherein each of the multiple mirrors under a respective one of the series acoustic resonators is formed in a p-type doped region of a substrate, and each of the multiple mirrors under a respective one of the shunt acoustic resonators is formed in an n-type doped region of the substrate.

13. The chip of any one of clauses 8 to 12, wherein each of the acoustic resonators comprises:
a bottom electrode;
a top electrode; and
a piezoelectric layer between the top electrode and the bottom electrode.

14. The chip of any one of clauses 8 to 13, wherein each of the first plurality of porous silicon layers has a porosity between 20% and 70%.

15. A system, comprising:
an antenna;
an acoustic resonator coupled to the antenna; and
a mirror under the acoustic resonator, the mirror including:
a first plurality of porous silicon layers; and
a second plurality of porous silicon layers, wherein the mirror alternates between the first plurality of porous silicon layers and the second plurality of porous silicon layers, and each of the first plurality of porous silicon layers has a higher porosity than each of the second plurality of porous silicon layers.

16. The system of clause 15, further comprising an amplifier coupled to the acoustic resonator.

17. The system of clause 15, further comprising a frequency downconverter coupled to the acoustic resonator.

18. The system of any one of clauses 15 to 17, wherein each of the first plurality of porous silicon layers has a porosity between 20% and 70%.

19. The system of any one of clauses 15 to 18, wherein the acoustic resonator comprises:
a bottom electrode;
a top electrode; and
a piezoelectric layer between the top electrode and the bottom electrode.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “approximately,” as used herein with respect to a stated value or a property, is intended to indicate being within 10% of the stated value or property and/or within typical manufacturing and design tolerances. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first object may be coupled to a second object even though the first object is never directly physically in contact with the second object.

The previous description of the disclosure is provided to enable any person skilled in the art to make or use the aspects of the disclosure. Various modifications to the aspects of the disclosure will be readily apparent to those skilled in the art, and the generic principles defined herein may be applied to other variations without departing from the spirit or scope of the disclosure. Thus, the claims are not intended to be limited to the aspects described herein, but are to be accorded the widest scope consistent with the principles and novel features disclosed herein. As used herein, reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. Similarly, a phrase referring to “A and/or B” is intended to cover: A, B, and A and B. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

What is claimed is:

1. A chip, comprising:
an acoustic resonator; and
a mirror under the acoustic resonator, the mirror including:
a first plurality of porous silicon layers; and
a second plurality of porous silicon layers, wherein the mirror alternates between the first plurality of porous silicon layers and the second plurality of porous silicon layers, and each of the first plurality of porous silicon layers has a higher porosity than each of the second plurality of porous silicon layers.

2. The chip of claim 1, wherein each of the first plurality of porous silicon layers has a porosity between 20% and 70%.

3. The chip of claim 1, wherein the mirror is formed in a p-type doped region of a substrate.

4. The chip of claim 1, wherein the mirror is formed in an n-type doped region of a substrate.

5. The chip of claim 1, wherein the acoustic resonator comprises:
a bottom electrode;
a top electrode; and
a piezoelectric layer between the top electrode and the bottom electrode.

6. The chip of claim 5, wherein the mirror is under the bottom electrode.

7. The chip of claim 6, further comprising a dielectric layer between the bottom electrode and the mirror.

8. A chip, comprising:
a filter comprising multiple acoustic resonators; and
multiple mirrors, wherein each of the multiple mirrors is under a respective one of the multiple acoustic resonators, and each of the mirrors includes:
a first plurality of porous silicon layers; and
a second plurality of porous silicon layers, wherein each mirror alternates between the first plurality of porous silicon layers and the second plurality of porous silicon layers, and each of the first plurality of porous silicon layers has a higher porosity than each of the second plurality of porous silicon layers.

9. The chip of claim 8, wherein the multiple acoustic resonators are coupled in a ladder configuration.

10. The chip of claim 8, wherein the multiple acoustic resonators comprise series acoustic resonators and shunt acoustic resonators, the series acoustic resonators are coupled in series between a first terminal and a second terminal of the filter, and each of the shunt acoustic resonators is coupled between a respective one of the series acoustic resonators and a third terminal of the filter.

11. The chip of claim 10, wherein each of the multiple mirrors under a respective one of the series acoustic resonators is formed in an n-type doped region of a substrate, and each of the multiple mirrors under a respective one of the shunt acoustic resonators is formed in a p-type doped region of the substrate.

12. The chip of claim 10, wherein each of the multiple mirrors under a respective one of the series acoustic resonators is formed in a p-type doped region of a substrate, and each of the multiple mirrors under a respective one of the shunt acoustic resonators is formed in an n-type doped region of the substrate.

13. The chip of claim 8, wherein each of the acoustic resonators comprises:
a bottom electrode;
a top electrode; and
a piezoelectric layer between the top electrode and the bottom electrode.

14. The chip of claim 8, wherein each of the first plurality of porous silicon layers has a porosity between 20% and 70%.

15. A system, comprising:
an antenna;
an acoustic resonator coupled to the antenna; and
a mirror under the acoustic resonator, the mirror including:
a first plurality of porous silicon layers; and
a second plurality of porous silicon layers, wherein the mirror alternates between the first plurality of porous silicon layers and the second plurality of porous silicon layers, and each of the first plurality of porous silicon layers has a higher porosity than each of the second plurality of porous silicon layers.

16. The system of claim 15, further comprising an amplifier coupled to the acoustic resonator.

17. The system of claim 15, further comprising a frequency downconverter coupled to the acoustic resonator.

18. The system of claim 15, wherein each of the first plurality of porous silicon layers has a porosity between 20% and 70%.

19. The system of claim 15, wherein the acoustic resonator comprises:
a bottom electrode;
a top electrode; and
a piezoelectric layer between the top electrode and the bottom electrode.
